(19) United States
(12) Patent Application Publication
(10) Pub. No.: US 2025/0067823 A1
(43) Pub. Date: Feb. 27, 2025

(54) SENSOR FOR MAGNETIC RESONANCE IMAGING SYSTEM, AND ASSOCIATED SYSTEM AND EXAMINATION TUNNEL

(71) Applicants: CENTRE NATIONAL DE LA RECHERCHE SCIENTIFIQUE (CNRS), Paris (FR); UNIVERSITE CLAUDE BERNARD LYON 1, Villeurbanne (FR); ECOLE CENTRALE DE LYON, Écully (FR); INSTITUT NATIONAL DES SCIENCES APPLIQUÉES DE LYON, Villeurbanne (FR)

(72) Inventors: Simon LAMBERT, Clermont-Ferrand (FR); Michel CABRERA, Lyon (FR); Philippe LOMBARD, Anthon (FR); Tony GERGES, Villeurbanne (FR); Vincent SEMET, Lentilly (FR); Jean-Lynce GNANAGO, Lyon (FR)

(21) Appl. No.: 18/719,721

(22) PCT Filed: Dec. 12, 2022
(86) PCT No.: PCT/FR2022/052313

§ 371 Date: Jun. 13, 2024

(30) Foreign Application Priority Data
Dec. 13, 2021 (FR) 2113415

(51) Int. Cl. G01R 33/34

(52) U.S. Cl. CPC G01R 33/34

(57) ABSTRACT

A magnetic resonance imaging system that includes an array of antennas that includes a substrate, a plurality of antennas arranged on a first face of the substrate, and a plurality of guard rings. The guard rings are arranged only on the second face of the substrate, opposite the first face. A projection of each of the antennas on the second face of the substrate being circumscribed within a specific guard ring. The guard rings are spaced apart from one another.

### TECHNICAL FIELD

The present invention relates to the field of magnetic resonance imaging (MRI) systems, and more particularly concerns a sensor for magnetic resonance imaging including an array of antennas, and an examination tunnel and a system including such a sensor.

### BACKGROUND

Generally, a magnetic resonance imaging system comprises a processing module reconstituting an image from data generated by an array of antennas. The sizing of the array of antennas and its integration into a support makes it possible to carry out the imaging examination on a human being.

### SUMMARY

A magnetic resonance imaging system that includes an array of antennas that includes a substrate, a plurality of antennas arranged on a first face of the substrate, and a plurality of guard rings. The guard rings are arranged only on the second face of the substrate, opposite the first face. A projection of each of the antennas on the second face of the substrate being circumscribed within a specific guard ring. The guard rings are spaced apart from one another.

### BRIEF DESCRIPTION OF THE DRAWINGS

Other aims, features and advantages of the invention will appear upon reading the following description, given solely by way of non-limiting example, and made with reference to the appended drawings wherein:

FIG. 1 illustrates one example of a magnetic resonance imaging system according to the invention,

FIG. 2 schematically illustrates one example of a sensor according to the invention,

FIG. 3 illustrates one example of an array of antennas according to the invention,

FIG. 4 illustrates another example of an array of antennas according to the invention,

FIG. 5 illustrates another example of an array of antennas according to the invention, and

FIG. 6 illustrates one example of an examination tunnel according to the invention.

### DETAILED DESCRIPTION

As noted, generally, a magnetic resonance imaging system comprises a processing module reconstituting an image from data generated by an array of antennas.

The sizing of the array of antennas and its integration into a support makes it possible to carry out the imaging examination on a human being.

Such a sizing and support is not suitable for carrying out an MRI examination of an animal, for example a pet such as a dog or a cat having smaller dimensions than those of a human body.

Such an array of antennas integrated into the support is difficult to adapt to the morphology of an animal.

Furthermore, it is necessary to magnetically decouple the antennas of the array of antennas from one another to obtain reliable MRI examination results.

In order to perform this decoupling, it is known to superimpose adjacent antennas of the array of antennas.

However, when the array of antennas is bent to conform to a part of the body of an animal of dimensions smaller than those of a human body, the antennas move closer together under the effect of the bending of the array of antennas so that the decoupling of the antennas is no longer ensured satisfactorily.

In order to magnetically decouple the antennas of the array of antennas, it is also known to add capacitors connecting adjacent antennas that do not overlap.

However, it is necessary to insert these capacitors into the array of antennas, which requires space.

Furthermore, the capacitors are generally welded to the antennas, imposing a control of the quality of the welds.

In addition, it is necessary to adjust the values of the capacitors in order to obtain the magnetic decoupling, the adjustment of these values being a tedious step.

It is also known to surround each antenna of the array of antennas in a guard ring to magnetically decouple the antennas.

For this, the antennas are arranged on a first face of a flexible substrate.

The guard rings are arranged both on the first face of the substrate and on the second face opposite the substrate so that two adjacent guard rings are arranged on different faces, the projection on the first face of the ring of the second face overlaps the ring on the first face, and so that each antenna is surrounded by a guard ring or that the projection of each guard ring on the second face surrounds an antenna.

However, when the array of antennas is bent to conform to a part of the body of an animal, the guard rings come closer together under the effect of the bending of the array of antennas so that the decoupling of the antennas once again is no longer ensured satisfactorily.

In view of the foregoing, the invention proposes to overcome the aforementioned drawback.

The object of the invention is a sensor for magnetic resonance imaging system including an array of antennas comprising a substrate, a plurality of antennas arranged on a first face of the substrate, and a plurality of guard rings.

The guard rings are arranged only on a second face of the substrate opposite the first face, the projection of each of the antennas on the second face of the substrate being circumscribed within a specific guard ring. The guard rings are spaced apart from one another.

Thus, there is no overlap area between the guard rings.

The layout of a guard ring on the second face of the substrate around the projection of an antenna located on the first face of said substrate makes it possible to shield the magnetic field generated by the neighbouring antennas without significantly degrading the electromagnetic performance of this antenna.

Furthermore, as the antennas arranged on the first face of the substrate do not overlap one another and the rings arranged on the second face do not overlap one another.

Preferably, connection terminals of each antenna are arranged on the substrate outside of the guard ring associated with said antenna.

Advantageously, each antenna is connected to a magnetic decoupling circuit of said sensor arranged on the substrate outside of the guard ring associated with said antenna.

Preferably, the antennas and the rings are obtained by double-sided single layer screen printing.

Advantageously, the sensor comprises a flexible support whereon the substrate is arranged so that the array of antennas locally has a curvilinear shape and forms an acute bending angle.

“Flexible” means a support capable of deforming under the effect of stresses and of remaining in its deformed state after stopping these stresses.

The material of the flexible support may be any polymer having flexibility properties or able to be modelled by thermoforming techniques (polystyrene, polyethylene, polypropylene, polycarbonate, polyvinyl chloride, polymethyl methacrylate).

Preferably, the array of antennas is integrated into the flexible support by a moulded interconnect device method.

The moulded interconnect device method makes it possible to integrate electronic components, particularly the array of antennas directly into the injection moulded flexible support.

Another object of the invention is an examination tunnel for a magnetic resonance imaging system including a sensor as defined above.

Another object of the invention is a magnetic resonance imaging system comprising a sensor as defined above.

Preferably, the imaging system is configured for animal imaging.

Another object of the invention is a system for transmitting and receiving power comprising a sensor as described above.

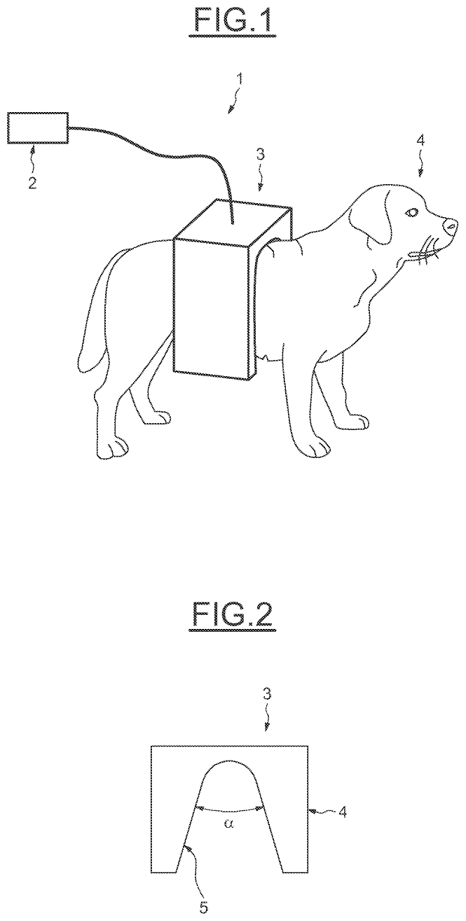

FIG. 1 shows an example of a magnetic resonance imaging system 1 including a magnetic resonance imaging device 2 and a sensor 3 connected to said device.

Here, the sensor 3 is sized to carry out a magnetic resonance imaging MRI examination of an animal, for example of the spine of a dog 4.

Of course, the sensor 3 may be designed to examine other parts of an animal, for example the head of a cat.

The sensor 3 measures the variation of the magnetic fields transmitted by atoms of the dog 4 excited by an excitation magnetic field.

Based on measurements delivered by the sensor 3, the device 2 reconstitutes images of the inside of the animal to establish a diagnosis.

In another application, the sensor 3 may be sized to carry out an examination of a human being.

FIG. 2 schematically illustrates one example of embodiment of the sensor 3.

The sensor 3 comprises a housing 4 and an array of antennas 5 attached on the housing 4.

The array of antennas 5 locally has a curvilinear shape and forms an acute a bending angle, that is to say less than or equal to 90°.

The array of antennas 5 makes it possible for example to conform to the shape of the back of a dog 4 in order to obtain high-quality imaging of the inside of the dog 3.

A reliable diagnosis can be established upon reading the high-quality image.

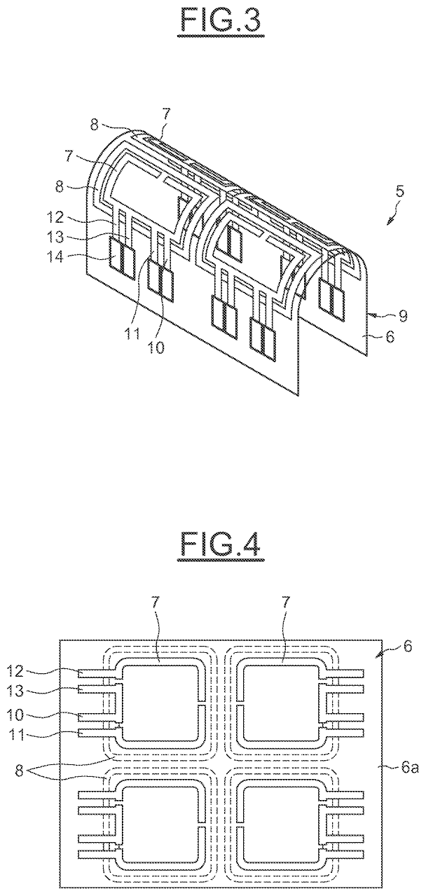

FIGS. 3, 4 and 5 schematically illustrate one example of the array of antennas 5.

The array of antennas 5 comprises a flexible substrate 6, a plurality of antennas 7, and guard rings 8.

The flexible substrate 6 is for example made of flexible polycarbonate.

The flexible substrate 6 is for example essentially flat (before bending) and comprises a first and a second face.

The array of antennas 5 further comprises a flexible support 9 whereon the substrate 6 is arranged.

The support 9 is for example made of a polymer three-dimensionally printed by stereolithography or made of a thermoplastic in wire or powder form shaped by a three-dimensional printing technique or other three-dimensional printing methods.

The thermoplastic comprises for example polylactic acid “PLA”, acrylonitrile butadiene styrene “ABS”, thermoformed polyvinyl chloride “PVC”, isostatic polypropylene “PP”, polycarbonate “C”, polyethylenimine “PEI”, polyetherketone “PEEK”, polyetherketoneketone “PEKK” or other materials used in three-dimensional printing.

The support 9 made from a polymer does not have electromagnetic compatibility in relation to a support made of ceramic.

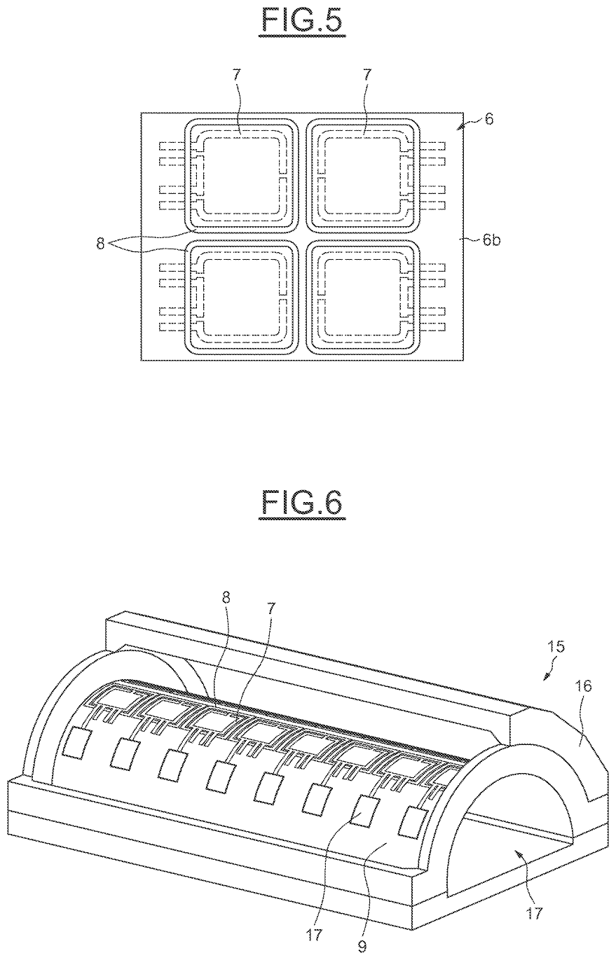

FIG. 4 illustrates the first face 6a of the substrate 6 and FIG. 5 illustrates the second face 6b of the substrate 6 opposite the first face 6a. The faces 6a and 6b delimit the thickness of the substrate.

On the first face 6a (FIG. 4) the antennas 7 are arranged so that they do not overlap.

The antennas 7 define a square in the example of embodiment illustrated. Alternatively, the antennas 7 may have other shapes, for example polygonal or also oval shapes in the shape of circles, multiple loops, etc.

Each antenna 7 further comprises a first set of connection terminals 10, 11 connecting the antenna 7 to the device 2, and a second set of connection terminals 12, 13 connecting the antenna 7 to a magnetic decoupling circuit (not shown).

It is distinguished in FIG. 4, by transparency of the substrate 6, the guard rings 8 arranged on the second face 6b of the substrate 6 and shown in dotted lines in this FIG. 4.

The second face 6b of the substrate whereon the guard rings 8 are arranged is illustrated in FIG. 5.

The substrate 6 comprising the antennas 7 and the rings 8 is attached on the support 9.

Each guard ring 8 is arranged on the second face 6b so that the projection of each of the antennas 7 on the second face 6b of the substrate is circumscribed within a guard ring 8 that is specific to it. In FIG. 5, the projection of each of the antennas 7 is shown in dotted lines.

The projection of each of the antennas 7 on the second face 6b of the substrate is circumscribed within a different guard ring 8.

The guard rings 8 are spaced apart from one another. In other words, the guard rings 8 do not overlap.

Adding a guard ring 8 on the second face 6b of the substrate 6 around an antenna 7 located on a first face 6a of said substrate 6 makes it possible to shield the magnetic field generated by the neighbouring antennas 7 without significantly degrading the electromagnetic performance of said antenna.

According to the size of the antenna 7 and the transmission frequency of the antenna 7, adding the guard ring 8 makes it possible to improve the electromagnetic performances of said antenna.

The value of the transmission frequency is chosen depending on the value of the excitation magnetic field.

The value of the transmission frequency is for example between 1 kHz and 1 GHZ, preferably between 30 MHz and 600 MHz.

The guard rings 8 make it possible to magnetically decouple the antennas 7.

As the guard rings 8 are arranged on a face different from that of the antennas 7, the rings 8 do not electrically interfere with the first and second sets of connection terminals of the antennas 7.

The connection terminals 10, 11, 12, 13 are arranged on the face 6a of the substrate 6 not comprising the rings 8.

The layout of the connection terminals on a face different from that of the guard antenna makes it possible to simplify the production of said terminals.

Furthermore, as the antennas 7 arranged on the first face 6a do not overlap with one another and the rings 8 arranged on the second face 6b do not overlap with one another.

The antennas 7 and the rings 8 made for example of copper are obtained for example by a known double-sided single layer screen printing method with copper ink on the substrate 6 then electroplating.

With reference again to FIG. 3, in order to further improve the magnetic decoupling of the antennas 7, the second set of connection terminals 10, 11 of each antenna 7 is connected to the magnetic decoupling circuit 14 (decoupling by pre-amplifier) arranged on the substrate 6 outside of the ring 8 of said antenna 7.

The decoupling circuit 14 is for example made of resistors and inductors.

Of course, the coupling of antennas 7 by adding rings 8 as described above applies to other types of antennas for applications other than magnetic resonance imaging.

FIG. 6 illustrates a partial section of an example of an examination tunnel 15.

The examination tunnel 15 comprises a frame 16 forming a cavity 17 wherein the object of the examination is inserted, for example the dog 4.

The cavity 17 is covered by the sensor 3 comprising the antennas 7 and the rings 8 arranged on the flexible support 9.

Amplification circuits 17 connected to the antennas 8 are arranged on the support 9.

Alternatively, the array of antennas is integrated into the flexible support 9 by a known moulded interconnect device method.

According to another alternative embodiment, the sensor does not comprise a flexible support 9.

The sensor 3 may further be implemented in fields of application other than medical imaging.

The sensor 3 may for example be implemented in other systems for applications other than resonance imaging, for example in systems for transmitting and receiving power or systems for detecting motion.

In particular, the invention as described makes it possible to improve the reproducibility, the reliability and the quality of images acquired by the sensor.

In accordance with common practice, the various features illustrated in the drawings may not be drawn to scale. The illustrations presented in the present disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

All examples and conditional language recited herein are intended for pedagogical objects to aid the reader in understanding the invention and the concepts contributed by the inventor to furthering the art, and are to be construed as being without limitation to such specifically recited examples and conditions. Although embodiments of the present disclosure have been described in detail, it should be understood that the various changes, substitutions, and alterations could be made hereto without departing from the spirit and scope of the present disclosure.

1. A sensor for a magnetic imaging system including an array of antennas comprising:
a substrate;
a plurality of antennas arranged on a first face of the substrate; and
a plurality of guard rings arranged only on a second face of the substrate opposite the first face, a projection of each of the antennas on the second face of the substrate being circumscribed within a specific guard ring, and the guard rings are spaced apart from one another.

2. The sensor according to claim 1, wherein connection terminals of each of the antennas are arranged on the substrate outside of the specific guard ring associated with each of the antennas.

3. The sensor according to claim 1, wherein each of the antennas is connected to a magnetic decoupling circuit of said sensor arranged on the substrate outside of the specific guard ring associated with each of the antennas.

4. The sensor according to claim 1, wherein the antennas and the guard rings are obtained by double-sided single layer screen printing.

5. The sensor according to claim 1, further comprising a flexible support whereon the substrate is arranged so that the array of antennas locally has a curvilinear shape and forms an acute bending angle.

6. The sensor according to claim 5, wherein the array of antennas is integrated into the flexible support by a moulded interconnect device method.

7. The magnetic resonance imaging system of claim 8, further comprising an examination tunnel that includes the sensor.

8. A magnetic resonance imaging system comprising:
a sensor that includes:
a substrate;
a plurality of antennas arranged on a first face of the substrate; and
a plurality of guard rings arranged only on a second face of the substrate opposite the first face, a projection of each of the antennas on the second face of the substrate being circumscribed within a specific guard ring, and the guard rings are spaced apart from one another.

9. The magnetic resonance imaging system according to claim 8, wherein the system is configured for animal imaging.

10. A system for transmitting and receiving power comprising:
a sensor that includes:
a substrate;
a plurality of antennas arranged on a first face of the substrate; and
a plurality of guard rings arranged only on a second face of the substrate opposite the first face, a projection of each of the antennas on the second face of the substrate being circumscribed within a specific guard ring, and the guard rings are spaced apart from one another.

11. The system of claim 10, wherein connection terminals of each of the antennas are arranged on the substrate outside of the specific guard ring associated with each of the antennas.

12. The system of claim 10, wherein each of the antennas are connected to a magnetic decoupling circuit of said sensor arranged on the substrate outside of the specific guard ring associated with each of the antennas.

13. The system of claim 10, wherein the antennas and the guard rings are obtained by double-sided single layer screen printing.

14. The system of claim 10, wherein the sensor further comprises a flexible support whereon the substrate is arranged to have a curvilinear shape and forms an acute bending angle.

15. The system of claim 14, wherein the antennas are integrated into the flexible support by a moulded interconnect device method.

16. The magnetic resonance imaging system of claim 8, wherein connection terminals of each of the antennas are arranged on the substrate outside of the specific guard ring associated with each of the antennas.

17. The magnetic resonance imaging system of claim 8, wherein each antenna is connected to a magnetic decoupling circuit of said sensor arranged on the substrate outside of the specific guard ring associated with said antenna.

18. The magnetic resonance imaging system of claim 8, wherein the antennas and the guard rings are obtained by double-sided single layer screen printing.

19. The magnetic resonance imaging system of claim 8, wherein the sensor further comprises a flexible support whereon the substrate is arranged to have a curvilinear shape and forms an acute bending angle.

20. The magnetic resonance imaging system of claim 19, wherein the antennas are integrated into the flexible support by a moulded interconnect device method.
